(19) United States
(12) Patent Application Publication
(10) Pub. No.: US 2024/0421040 A1
(43) Pub. Date: Dec. 19, 2024

(54) APPARATUS INCLUDING TSV STRUCTURE

(71) Applicant: MICRON TECHNOLOGY, INC., Boise, ID (US)

(72) Inventors: SEIJI NARUI, Sagamihara (JP); SHIRO UCHIYAMA, Tokyo (JP); BANG NING HSU, West Central (TW); KAYOKO SHIBATA, Tokyo (JP); FUMIYUKI OSANAI, Sagamihara (JP)

(73) Assignee: MICRON TECHNOLOGY, INC., Boise, ID (US)

(21) Appl. No.: 18/739,937

(22) Filed: Jun. 11, 2024

Related U.S. Application Data
(60) Provisional application No. 63/508,498, filed on Jun. 15, 2023.

(51) Int. Cl. H01L 23/48; H01L 23/00; H01L 23/528; H10B 80/00

(52) U.S. Cl. CPC H01L 23/481; H01L 23/528; H01L 24/16; H10B 80/00; H01L 24/17; H01L 24/32; H01L 2224/16145; H01L 2224/17519; H01L 2224/32225; H01L 2924/1431; H01L 2924/1434

(57) ABSTRACT

According to one or more embodiments of the disclosure, an apparatus comprises a logic die including a plurality of first through-silicon vias (TSVs), and a core die on the logic die including a plurality of TSVs. The number of the first TSVs in the logic die is different from the number of the second TSVs in the core die.

### CROSS REFERENCE TO RELATED APPLICATION(S)

This application claims priority to U.S. Provisional Application No. 63/508,498, filed Jun. 15, 2023. The aforementioned application is incorporated herein by reference, in its entirety, for any purpose.

### BACKGROUND

High data reliability, high speed of memory access, lower power consumption, and reduced chip size are features that are demanded from semiconductor memory. Some three-dimensional (3D) memory devices may be formed by stacking memory dies (or memory chips) vertically and interconnecting the stacked memory dies using through-silicon vias (TSVs). Benefits of the 3D memory devices include shorter interconnects which reduce signal delays and power consumption, a larger number of vertical vias between layers which allow wide bandwidth buses between functional blocks in different layers, and a considerably smaller footprint. Thus, the 3D memory devices contribute to higher memory access speed, lower power consumption, and chip size reduction. Example 3D memory devices include a High Bandwidth Memory (HBM) and a Hybrid Memory Cube (HMC). HBM is a type of memory including a high-performance dynamic random access memory (DRAM) interface die and vertically stacked DRAM dies. HMC is another type of such memory.

### BRIEF DESCRIPTION OF THE DRAWINGS

FIG. 1 depicts an example of at least part of a memory device including a logic die and a plurality of core dies in a cross-sectional view according to an embodiment of the disclosure.

FIG. 2 depicts an example of at least part of a memory device including a logic die and a plurality of core dies in an enlarged cross-sectional view according to an embodiment of the disclosure.

FIG. 3 depicts an example of at least part of a memory device including a logic die and a plurality of core dies in a cross-sectional view according to an embodiment of the disclosure.

FIGS. 4A and 4B depict an example of at least part of a logic die and a core die, respectively, in a plan view according to an embodiment of the disclosure.

FIG. 5 depicts an example of a structure including a frontside bump and TSVs in a cross-sectional view according to an embodiment of the disclosure.

FIG. 6 depicts an example of at least part of a memory device including a logic die and a plurality of core dies in a cross-sectional view according to an embodiment of the disclosure.

FIGS. 7A and 7B depict an example of at least part of a logic die and a core die, respectively, in a plan view according to an embodiment of the disclosure.

FIG. 8 depicts an example of a schematic configuration of a semiconductor system according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for case of illustration. In the drawings, the dimensions and dimensional ratios of each unit do not necessarily match the actual dimensions and dimensional ratios in the embodiments.

According to some embodiments of the disclosure, a semiconductor device, such as a memory device, and another semiconductor device, such as a processor, may be provided on a packaging substrate. In some embodiments, a memory device may be a dynamic random access memory (DRAM), a High Bandwidth Memory (HBM), or a Hybrid Memory Cube (HMC). In some embodiments, a processor may be a central processor, a graphical processor, a memory controller, or the like. In some embodiments, an interposer may be provided between the semiconductor devices and the packaging substrate. The semiconductor devices may be coupled to the interposer by external terminals, such as bumps or microbumps. The external terminals may form electrodes between the semiconductor devices and the interposer. The interposer may be stacked on and coupled to the packaging substrate by, for example, solder balls.

According to some embodiments of the disclosure, a semiconductor device may have a layered structure in which a plurality of core dies (or core chips) are stacked with one another on a logic die (or a logic chip). The logic die may also be referred to as a base logic die. The logic die may include an interface (IF) die (or an IF chip). The logic die may be coupled to an interposer via external terminals. In some embodiments, the core dies and the logic die may be semiconductor chips each including semiconductor substrates, such as silicon (Si) substrates, and further including circuits, such as a command circuit, a control circuit and a buffer circuit. In some embodiments, each single die may also be referred to as a semiconductor device, and a plurality of dies form a layered or stacked structure of multiple semiconductor devices. In some embodiments, each of the core dies includes a plurality of wiring layers, such as metal layers, provided by for example a back-end-of-line (BEOL) process and/or a middle-of-line (MOL) process, on the semiconductor substrate. The wiring layers may be stacked and connected with one another via, for example, conductive contacts. In some embodiments, the core dies may be provided in a face-up manner wherein an uppermost wiring layer among the wiring layers of each die faces upwards. In some embodiments, the core dies may be provided in a face-down manner wherein an uppermost wiring layer among the wiring layers of each die faces downwards.

In a case of a memory device, the plurality of core dies may include a plurality of memory dies (or memory chips) stacked on the base logic die. The number of the plurality of memory dies may be four or eight, but is not limited thereto. Each of the memory dies may include a memory array for storing data and further include circuits for performing memory operations, such as read and write operations.

In some embodiments, the plurality of core dies and the logic die may be coupled to one another by one or more multilevel conductive structures and one or more conductive vias. The logic die may provide one or more interfaces which provide signals to and/or receive signals from the core dies. The signals may be external signals transmitted by the logic die. The multilevel conductive structure and the conductive vias may be electrically connected to each other and to the logic die and provide input/output lines (I/Os) between the core dies and the logic die. The multilevel conductive structures may include multilevel wirings and multilevel contacts electrically connected to each other. The multilevel wirings may include a plurality of conductive (e.g., metal) wirings in multiple layers. The multilevel contacts may include conductive contact plugs in multi layers. The multilevel conductive structures may include other conductive elements, components, substructures, and such, as appropriate. The conductive vias may be through-silicon vias (TSVs). The TSVs may be provided to the core dies and the logic die, vertically penetrating the respective dies including their semiconductor substrates in the respective layers. Bumps may also be provided between adjacent dies in upper and lower layers. The bumps may be arranged in alignment with the TSVs as well as at least part (such as the plugs) of the conductive structures in a horizontal plane. The TSVs, the bumps, and the conductive structures provide electrical paths to electrically connect or couple the adjacent dies.

The TSVs of the respective dies may be aligned with one another and form TSV pillars or columns vertically extending as terminals providing connections between the dies in upper and lower layers. The TSV pillars may provide the I/Os between the dies. In some embodiments, in a case of a horizontal plane having an X-Y coordinate plane with an X-axis and a Y-axis perpendicular to each other, one TSV of one die in an upper layer may have the same (or substantially the same within reasonable tolerances of fabrication, measurement, etc.) X-axis coordinate and Y-axis coordinate as another TSV of another die in an adjacent lower layer. The two TSVs thus penetrate, at the same (or substantially the same) X-Y coordinates, front and back surfaces of the two dies along a vertical plane perpendicular to the horizontal plane. The bumps may also have the same (or substantially the same) X-Y coordinates as the corresponding TSVs in the horizontal plane. As described in detail with reference to the accompanying drawings herein, in some embodiments, TSVs may not be provided in some areas in the dies or between the adjacent dies.

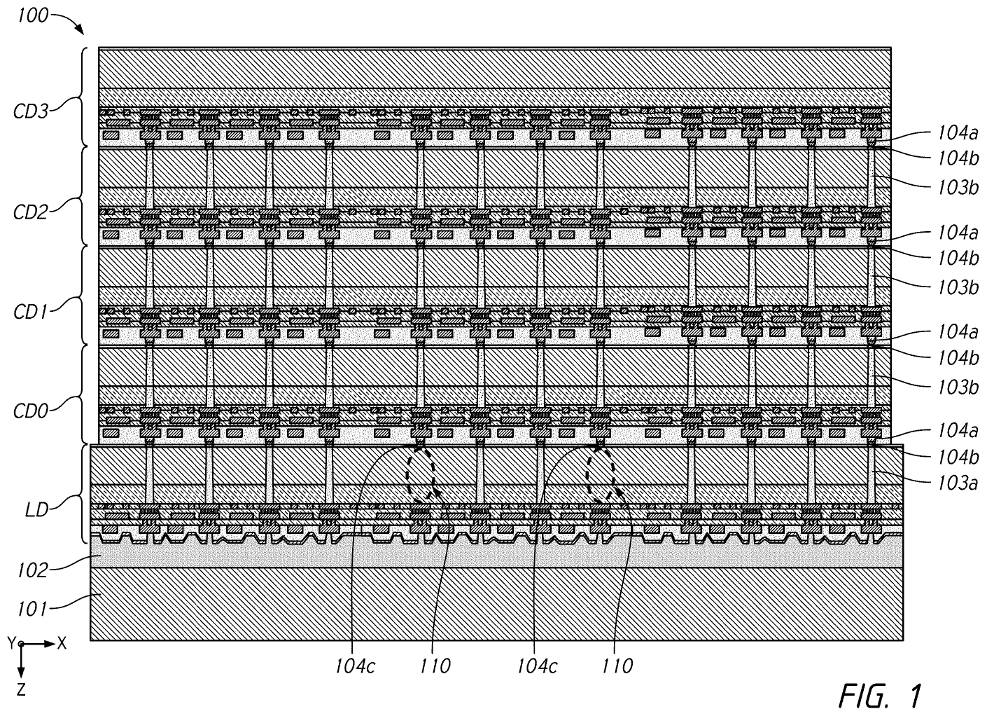

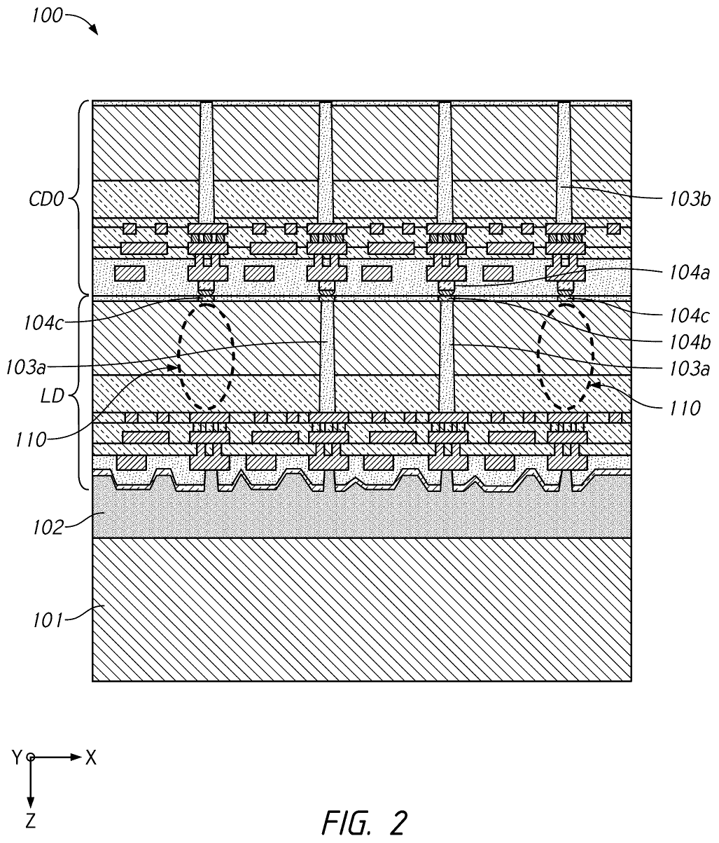

FIGS. 1-3 depict an example of at least part of a memory device 100 including a logic die LD and a plurality of core dies CDs (CD0-CD3) in a cross-sectional view or in an enlarged cross-sectional view according to some embodiments of the disclosure. The logic die LD is provided on and attached to a carrier layer 101 by an adhesive layer 102. The carrier layer may include a silicon substrate or a glass substrate. The plurality of core dies CDs are stacked on the logic die LD, forming a stacked or layered structure in a vertical direction (or a direction along a Z axis illustrated in the drawing, for example). The core dies CDs are stacked in a face-down manner. While there are four core dies CD0-CD3 illustrated in the drawing, the number of the core dies is not limited thereto.

The logic die LD includes a plurality of TSVs (may also be referred to as first TSVs) 103a. Each of the plurality of core dies CDs includes a plurality of TSVs (may also be referred to as second TSVs) 103b. The first TSVs 103a and the second TSVs 103b may collectively be referred to as TSVs 103. The TSVs 103 are aligned with each other and provide electrical paths between adjacent lower and upper dies in the vertical direction.

Between the adjacent TSVs 103 are bumps 104a and 104b. The bumps 104a are provided to uppermost layers of the respective core dies CDs. The bumps 104b are provided to lowermost layers of the respective core dies CDs. The bumps 104a and 104b may also be referred to as frontside bumps and backside bumps, respectively, in the example where the core dies CDs are stacked in the face-down manner. The frontside bumps 104a are at least electrically coupled or connected to uppermost metal wirings (or uppermost metal wiring layers) of the core dies CDs. The uppermost metal wirings may be part of multilevel conductive structures of the respective core dies CDs. The multilevel conductive structures include a plurality of multilevel conductive wirings (such as metal wirings) and a plurality of multilevel conductive contacts (such as contact plugs) as illustrated. The wirings and the contacts are electrically connected to each other to form conductive paths in the respective core dies CDs. The logic die LD may include multilevel conductive structures the same as or similar to those of the core dies CDs. The frontside bumps 104a may be part of the multilevel conductive structures or at least electrically connected to the multilevel conductive structures. The backside bumps 104b are electrically connected to the frontside bumps 104a and also to ends of the TSVs 103. Each end may be referred to as a lower end, which is illustrated at the top of each TSV 103 in the drawing showing the face-down stacking manner. The frontside bumps 104a and the backside bumps 104b together electrically connect the adjacent core dies CDs in the lower and upper stacked layers. The frontside bumps 104a and the backside bumps 104b are aligned with the TSVs 103a and 103b. The frontside bumps 104a, the backside bumps 104b, and the TSVs 103a and 103b provide vertical paths to electrically couple or connect the adjacent dies CDs and LD. The bumps 104a and 104b may include, for example, copper (Cu), nickel (Ni), tin (Sn), indium (In), or a combination thereof, but are not limited thereto.

The logic die LD includes one or more areas 110 where the TSV 103a are not provided. Because of the areas 110, the logic die LD has less population of TSVs 103a than the population of TSVs 103b of the core dies CDs, and the logic die LD is less dense than the core dies CDs in terms of the number of the TSVs 103 in the corresponding areas. These areas 110 may be referred to as TSV depopulated areas. The number of the TSVs 103a in the logic die LD is hence less than the number of the TSVs 103b in each of the core dies CDs. This allows further variations and greater flexibility in the number of the TSVs 103 between the logic die LD and the core dies CDs.

In an HBM, as one example, a logic die has a different floorplan from core dies. The core dies may require an extensively greater number of power and ground TSVs for adequate power delivery. A greater number of the power and ground TSVs have a greater impact on the logic die due to restrictions to arrange required circuits to specific places on the logic die. The present embodiments and examples achieve both better power delivery to core dies and good circuit placement on a logic die by reducing the number of TSVs on the logic die than that on each of the core dies and thereby making the TSVs on the logic die less dense than the TSVs on each of the core dies. The better power delivery leads to a better performance of a memory device. The better circuit placement also leads to a better performance and hence a lower cost of a memory device.

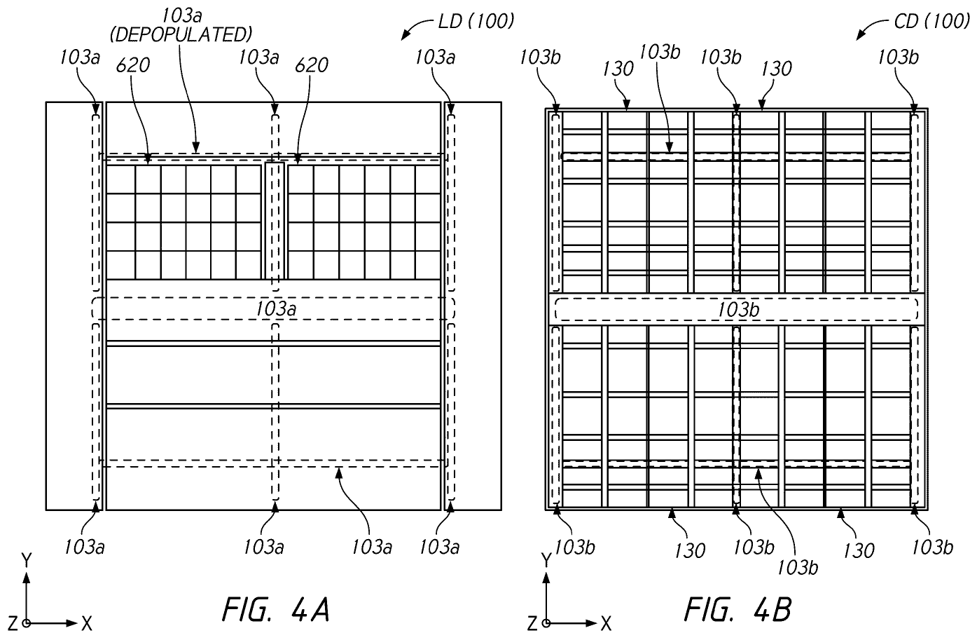

FIGS. 4A and 4B depict an example of at least part of the logic die LD and the core die CD of the memory device 100, respectively, in a plan view according to an embodiment of the disclosure. The TSVs 103a and 103b may be provided to peripheral regions besides logic array regions 120 and cell array regions 130 in the logic die LD and the core die CD. Some peripheral regions may be in left and right sides and upper and lower sides of the array regions 120/130 in a plan view as illustrated in the drawing. Some peripheral regions may be at central regions of the dies where the array regions 120/130 are not provided in a plan view as illustrated in the drawing. In the peripheral regions of the logic die LD, for example, there may be various circuits and elements, such as built-in self-test (BIST) circuits, anti-fuse circuits, voltage regulators, power supply units, and amplifiers. While some of the peripheral regions of the logic die LD have sufficient space for the TSVs 103a, some of the peripheral regions may have less TSV space than the corresponding regions in the core die CD. For instance, the upper peripheral region above the array region 120 in the logic die LD in Y direction as illustrated in the drawing may have a smaller TSV space than the corresponding region in the core die CD. According to some embodiments of the disclosure, the number of the TSVs 103a in that upper peripheral region of the logic die LD may be significantly reduced to be, for example, one half or one third of or lesser than the number of the TSVs 103b in the corresponding region in the core die CD. Such depopulation or thinning out of the TSVs 103a effectively improves IR drop for, for example, a few mV or more. It also achieves effective improvement of TSV electromigration. The TSV depopulated area(s) may be provided to other peripheral areas of the logic die LD as appropriate.

Referring back to FIGS. 1-3, in the TSV depopulated areas 110, dummy backside bumps 104c are provided in place of the backside bumps 104b. The dummy backside bumps 104c may be thermal bumps, for example. A structure of each of the dummy backside bumps 104c may be the same or substantially the same as that of a thermal bump. The thermal bump may act as a solid-state heat bump and add thermal management functionality on the surface of the die. The structure of the thermal bump may be any conventional structure as appropriate. The dummy backside bumps 104c may function as or similar to the thermal bumps. In a case where the backside bump 104b is a Sn)/Cu bump, the dummy backside bump 104c that is not a Sn/Cu bump provides a barrier metal between the frontside bump 104a and silicon (Si) of a semiconductor die substrate and effectively mitigates a copper diffusion risk. In a case where the frontside bump 104a is a Ni)/Sn bump, the dummy backside bumps 104c may not be provided.

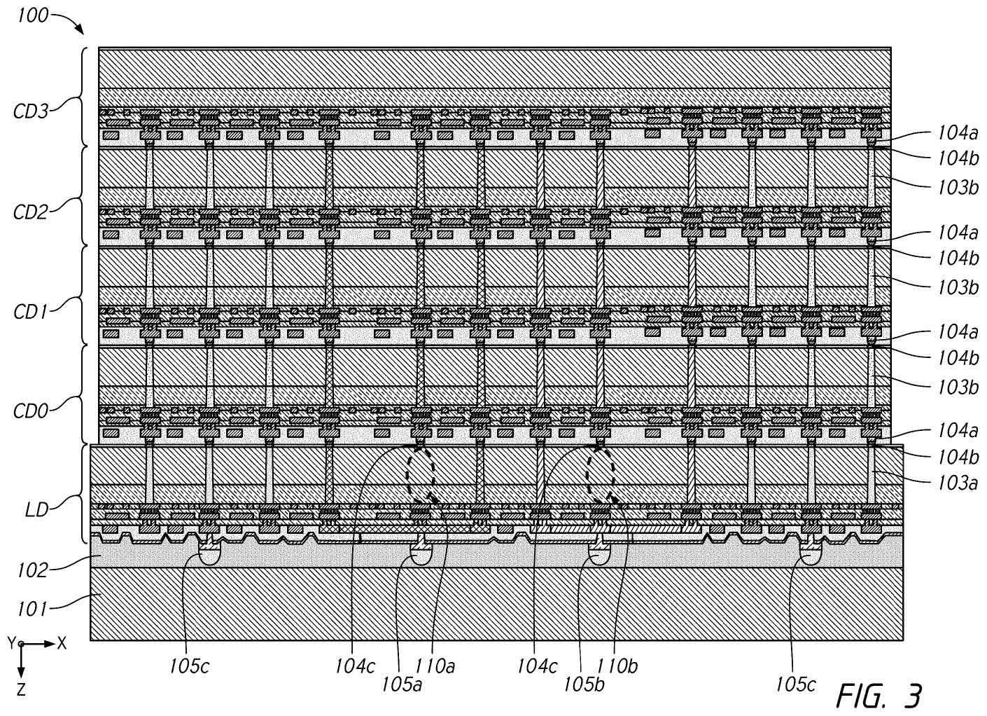

Referring to FIG. 3, there may be provided one or more ground voltage (VSS) bumps 105a, one or more power (PWR) bumps 105b, and one or more signal (SIG) bumps 105c connecting an uppermost layer of the face-down stacked logic die LD to the carrier layer 101. Such bumps 105a, 105b, and 105c may be microbumps. The TSV depopulated areas 110 (110a and 110b) may then be provided with respect to at least one of the VSS bumps 105a and at least one of the PWR bumps 105b. The TSV depopulated areas 110a and 110b effectively mitigate an electromigration risk and help to optimize the VSS and PWR current flow.

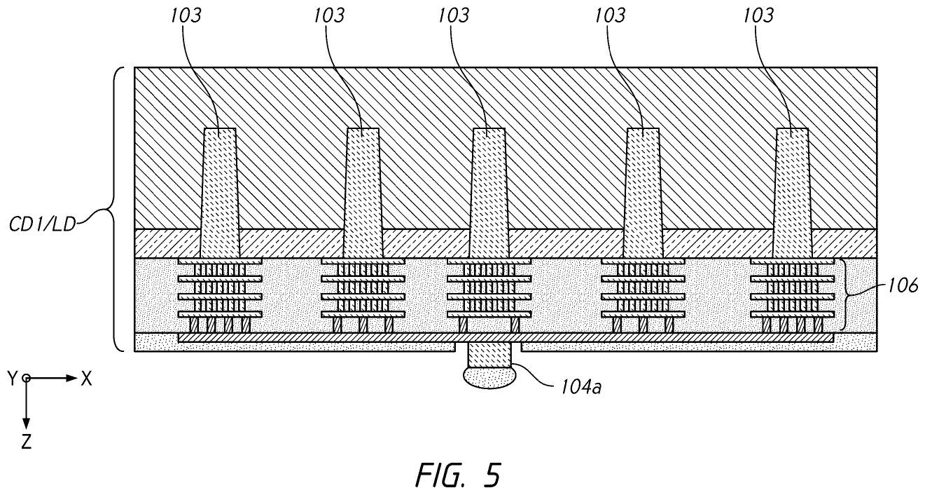

FIG. 5 depicts an example of a configuration of the frontside bump 104a and the TSVs 103 in a cross-sectional view according to an embodiment of the disclosure. Multilevel conductive structures 106 are also provided and are electrically connected to the corresponding TSVs 103 as well as the frontside bump 104a. In the example, the number of the frontside bump 104 is less than the number of the TSVs 103, unlike the examples of FIGS. 1-3 where the former number and the latter number are the same. This bump-TSV configuration helps to further optimize the current flow of the TSVs 103.

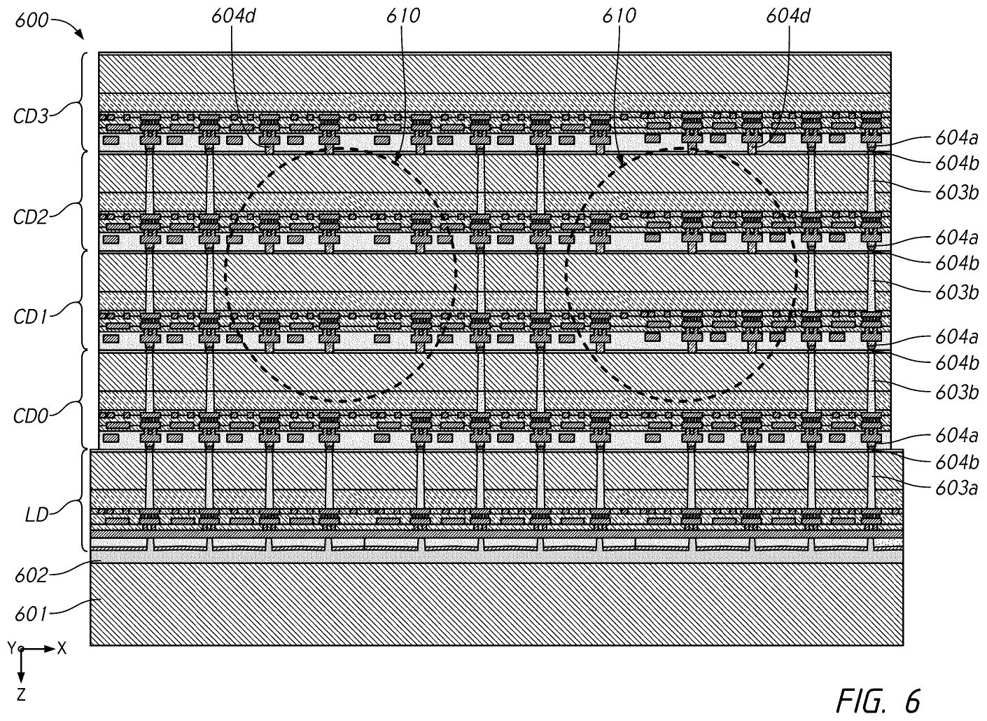

FIG. 6 depicts an example of at least part of a memory device 600 including a logic die LD and a plurality of core dies CDs (CD0-CD3) in a cross-sectional view according to an embodiment of the disclosure. The logic die LD, the core dies CDs, a carrier layer 601, an adhesive layer 602, a plurality of TSVs 603a and 603b, a plurality of frontside bumps 604a, and a plurality of backside bumps 604b are the same or substantially the same as the logic die LD, the core dies CDs, the carrier layer 101, the adhesive layer 102, the TSVs 103a and 103b, the frontside bumps 104a, and the backside bumps 104b, respectively. The dies LD/CD include multilevel conductive structures the same as or similar to those of the dies LD/CD illustrated in FIG. 1.

In the example depicted in FIG. 6, at least one of the core die CDs includes one or more areas 610 where the TSV 603b are not provided. Because of the areas 610, the core die CD has less population of TSVs 603b than the population of TSVs 603a of the logic die LD, and the core die CD is less dense than the logic die LD in terms of the number of the TSVs 603 in the corresponding areas. These areas 610 may be referred to as TSV depopulated areas. The number of the TSVs 603b in the core die CD is hence less than the number of the TSVs 603a in the logic die LD. This allows further variations and greater flexibility in the number of the TSVs 603 between the logic die LD and the core dies CDs, especially for an HBM which may have different floorplans between a logic die and a core die. Also, the power delivery among the dies and hence the device performance and cost will be effectively improved.

In the TSV depopulated areas 610 in the core dies CDs, dummy frontside bumps 604d are provided in place of the frontside bumps 604a. The dummy frontside bumps 604d may be thermal bumps, for example. A structure of each of the dummy frontside bumps 604d may be the same or substantially the same as a thermal bump. The thermal bump may act as a solid-state heat bump and add thermal management functionality on the surface of the die. The structure of the thermal bump may be any conventional structure as appropriate. The dummy frontside bumps 604d may function as or similar to the thermal bumps. In other examples, in addition to or as an alternative for the dummy frontside bumps 604d, dummy backside bumps similar to the dummy backside bumps 104c may be provided in the TSV depopulated areas 610 in the core dies CDs.

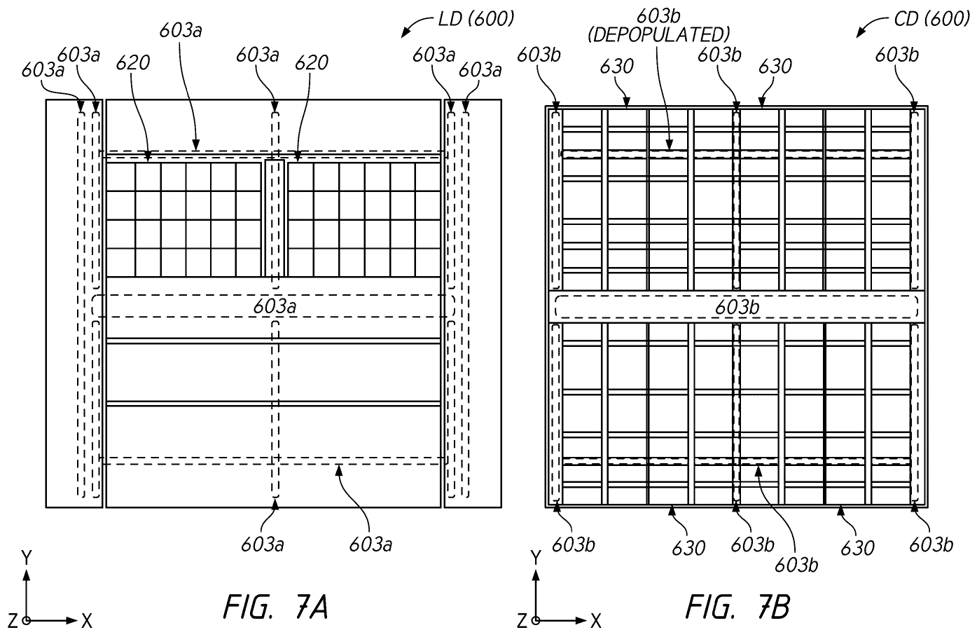

FIGS. 7A and 7B depict an example of at least part of the logic die LD and the core die CD of the memory device 600, respectively, in a plan view according to an embodiment of the disclosure. Similarly to the example depicted by FIGS. 4A and 4B, the TSVs 603a and 603b may be provided to the peripheral regions besides logic array regions 620 and cell array regions 630 in the logic die LD and the core die CD.

What is different from the example of FIGS. 4A and 4B is that the upper peripheral region of the core die CD has the TSV 603b depopulated region. The depopulation or thinning out of the TSVs 603b makes the number of the TSVs 603a appear to have increased in comparison with the number of the TSVs 603b. This effectively improves the power delivery, which consequently improves IR drop for, for example, a few mV or more. It also achieves effective improvement of TSV electromigration. The TSV depopulated area(s) may be provided to other peripheral regions of the core die CD as appropriate.

Also, referring to FIG. 7A, the logic die LD may have a greater number of the TSVs 603a than the TSVs 603b in the core die CD. For example, at least one of the peripheral regions (such as the right and left side peripheral regions as illustrated in the drawing) may be denser than the corresponding region in the core die CD in terms of the number of the TSVs 603. This is due to the greater space available in the peripheral regions of the logic die LD than the core die CD. This achieves further flexibility of the TSV arrangement.

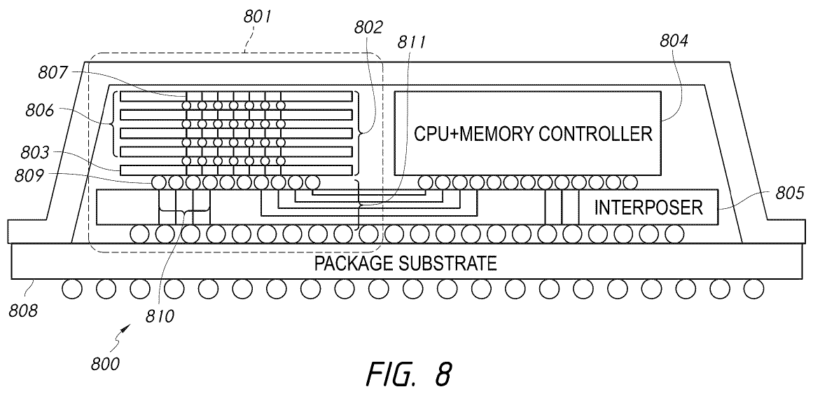

FIG. 8 depicts an example of a schematic configuration of a semiconductor system 800 according to an embodiment of the disclosure. The semiconductor system 800 includes an apparatus, which is a memory device 801 in an embodiment of the disclosure. The semiconductor system 800 may also include a central processing unit (CPU) and memory controller 804, which may be a controller chip, on an interposer 805 on a package substrate 808. The interposer 805 may include one or more power lines 810 which may supply power supply voltage from the package substrate 808. The interposer 805 may include a plurality of channels 811 that may interconnect the CPU and memory controller 804 and the semiconductor memory device 801. For example, the semiconductor memory device 801 may be a dynamic random access memory (DRAM). The memory controller 804 may provide a clock signal, a command signal, and may further transmit and receive data signals. The plurality of channels 811 may transmit the data signals between the memory controller and the memory device 801. The memory device 801 may include a plurality of dies (or chips) 802 including at least one interface (IF) die (or chip) 803 and a plurality of memory core dies (or chips) 806 stacked with each other. A number of the memory core dies 806 may not be limited to 4 and may be more or fewer as appropriate. Each of the memory core dies 806 may include a plurality of memory cells and circuitries accessing the memory cells. For example, the memory cells may be DRAM cells. The memory cells may be arranged in array. The memory device 801 may include conductive vias 807 which couple the IF die 803 and the memory core dies 806 by penetrating the IF die 803 and the memory core dies 806. The conductive vias 807 may be TSVs. TSVs may be the TSVs 103 or the TSVs 603. The IF die 803 may be coupled to the interposer 805 via interconnects 809. For example, the interconnects 809 may be microbumps having bump pitches of less than about or less than one hundred micrometers and exposed on an outside of the IF die 803. A portion of each of the interconnects 809 may be coupled to the one or more power lines 810. Another portion of each of the interconnects 809 may be coupled to one or more of the channels 811.

DRAM is merely one example of the memory device 801, and the embodiments and the above descriptions thereof are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the memory device 801. Furthermore, devices other than memory, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a logic die including a plurality of first through-silicon vias (TSVs); and
a core die on the logic die including a plurality of second TSVs, wherein
a number of the first TSVs in the logic die is different from a number of the second TSVs in the core die.

2. The apparatus according to claim 1, wherein the number of the first TSVs in the logic die is less than the number of the second TSVs in the core die.

3. The apparatus according to claim 2, wherein the logic die has a TSV depopulated area.

4. The apparatus according to claim 3, wherein the TSV depopulated area includes a dummy backside bump.

5. The apparatus according to claim 4, wherein the dummy backside bump has a same structure as a thermal bump.

6. The apparatus according to claim 1, wherein the number of the second TSVs in the core die is less than the number of the first TSVs in the logic die.

7. The apparatus according to claim 6, wherein the core die has a TSV depopulated area.

8. The apparatus according to claim 7, wherein the TSV depopulated area includes a dummy frontside bump.

9. The apparatus according to claim 8, wherein the dummy frontside bump has a same structure as a thermal bump.

10. The apparatus according to claim 1, wherein a number of frontside bumps in the logic die and/or the core die is less than the number of the first TSVs and/or the number of the second TSVs.

11. The apparatus according to claim 1, wherein the first and second TSVs include power TSVs and/or ground TSVs.

12. The apparatus according to claim 1, wherein the logic die includes an interface die, and the core die includes a plurality of core dies stacked on the logic die.

13. The apparatus according to claim 1, wherein the core die includes a memory die.

14. The apparatus according to claim 1, wherein the apparatus includes a memory device.

15. The apparatus according to claim 1, wherein
the apparatus further comprises a plurality of multilevel conductive structures each including a plurality of multilevel wirings and a plurality of multilevel contacts electrically connected to each other,
the logic die and the core die have the TSVs thereof electrically connected to the multilevel conductive structures, and
at least one of the logic die and the core die has a TSV depopulated area where the TSVs are not provided.

16. The apparatus according to claim 15, wherein
the apparatus further comprises a plurality of bumps electrically connected to the multilevel conductive structures and the TSVs, and
the TSV depopulated area has a plurality of dummy bumps in place of the plurality of bumps.

17. An apparatus, comprising:
a logic die and a core die each including a plurality of through-silicon vias (TSVs), wherein
at least one of the logic die and the core die includes a TSV depopulated area, and
a number of the TSVs in the TSV depopulated area in one of the logic die and the core die is less than a number of the TSVs in another one of the logic die and the core die.

18. The apparatus according to claim 17, wherein,
the TSV depopulated area includes a dummy bump, and
the dummy bump is a thermal bump.

19. The apparatus according to claim 17, wherein
the apparatus further comprises:
a plurality of multilevel conductive structures each including a plurality of multilevel wirings and a plurality of multilevel contacts electrically connected to each other; and
a plurality of bumps electrically connected to the multilevel conductive structures,
the logic die and the core die have the TSVs thereof electrically connected to the multilevel conductive structures via the bumps, and
the TSV depopulated area has a plurality of dummy bumps in place of the bumps.

20. An apparatus, comprising:
a logic die including:
a plurality of first multilevel conductive structures;
a plurality of first through-silicon vias (TSVs) electrically connected to the first multilevel conductive structures; and
a plurality of first bumps electrically connected to the first TSVs; and
a plurality of core dies on the logic die, each of the core dies including:
a plurality of second multilevel conductive structures;
a plurality of second TSVs electrically connected to the second multilevel conductive structures; and
a plurality of second bumps electrically connected to the second TSVs, wherein
at least one of the logic die and the core die includes a plurality of TSV depopulated areas where the TSVs are not provided, and
the TSV depopulated areas include a plurality of dummy bumps in place of at least one of the first bumps and the second bumps.
